(19) United States
(12) Patent Application Publication
(10) Pub. No.: US 2010/0126584 A1
(43) Pub. Date: May 27, 2010

(54) SOLAR CELLS AND SOLAR CELL MODULES

(75) Inventors: Kwang-Soo Seol, Yongin-si (KR); Yoon-Dong Park, Yongin-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/619,042

(22) Filed: Nov. 16, 2009

(30) Foreign Application Priority Data
Nov. 21, 2008 (KR) 10-2008-0116297

(51) Int. Cl. H01L 31/00

(52) U.S. Cl. 136/259; 136/261

(57) ABSTRACT

A solar cell module includes a solar cell provided at a center area of a support to expose an edge area of the support. An optical waveguide layer is provided on the edge area of the support to concentrate light to the solar cell.

This U.S non-provisional patent application claims priority to Korean Patent Application No. 10-2008-0116297, filed on Nov. 21, 2008, and all the benefits accruing therefrom under 35 U.S.C. §119, the contents of which in its is herein incorporated by reference.

### BACKGROUND

1. Field

The disclosure relates to solar cells and solar cell modules using the same.

2. Description of the Related Art

Solar cells generally include a semiconductor in which an electron-hole pair is generated when light is incident upon the solar cell. Due to an electric field generated at a PN junction in the semiconductor, electrons migrate to an N-type semiconductor while holes migrate to a P-type semiconductor, thereby generating electrical power. Since components used in the solar cell are expensive, there is difficulty in manufacturing a large-sized solar cell. Sunlight condensing technologies have been developed to manufacture large-sized solar cells and increase their manufacturing costs and efficiency.

### SUMMARY

An aspect of the present invention provides a solar cell. In one embodiment, the solar cell may include a substrate and a light-receiving body including a first semiconductor region of a first conductivity type and a second semiconductor region of a second conductivity type, which are formed on the substrate. The first semiconductor region is in contact with the second semiconductor region, and the second conductivity type is different from the first conductivity type. The first and second semiconductor regions have a PN junction surface, which is substantially perpendicular to the substrate.

The first semiconductor region may have a hollow column and include a first inner surface and a first outer surface; the first outer surface being opposed to the first inner surface. The second semiconductor region may include a second inner surface, which is in contact with the first outer surface. The PN junction surface may be disposed between the first outer surface and the second inner surface.

The solar cell may further include a first electrode, which is in contact with the first inner surface of the first semiconductor region and a second electrode, which is in contact with a second outer surface of the second semiconductor region. The second outer surface is opposed to the second inner surface of the second semiconductor region.

Another aspect of the present invention provides a solar cell module. In some embodiments, the solar cell module may include a support, a solar cell disposed adjacent to a center area of the support and provided to expose an edge area of the support, and an optical waveguide layer provided on the edge area of the support to concentrate and direct light to the solar cell.

The solar cell may have a PN junction surface, which is substantially perpendicular to the support.

### BRIEF DESCRIPTION OF THE DRAWINGS

The above and other aspects, advantages and features of this disclosure will become more apparent by describing in further detail exemplary embodiment thereof with reference to the accompanying drawings, in which:

FIG. 1A is an exemplary schematic plan (top view) of a solar cell according to some embodiments, and FIG. 1B is an exemplary cross-sectional view taken along the line I-I′ in FIG. 1A.

FIG. 2 is an exemplary schematic plan (top view) of a solar cell.

FIGS. 3A to 7A are exemplary schematic plans (top views) illustrating a method of manufacturing a solar cell, and FIGS. 3B to 7B are exemplary schematic cross-sectional views taken along the lines II-II′ in FIGS. 3A to 7A, respectively.

FIG. 8 is an exemplary schematic cross-sectional view of a solar cell module.

FIGS. 9A and 9B are exemplary schematic top surface views of the solar cell module shown in FIG. 8.

FIGS. 10A and 10B illustrate examples of a first optical coupler.

FIG. 11 illustrates the procedure of transmitting light through an optical waveguide.

FIG. 12 is an exemplary schematic cross-sectional view of a solar cell module.

FIGS. 13 to 15 are exemplary schematic cross-sectional views of a solar cell module.

FIG. 16 is an exemplary schematic diagram illustrating a solar cell array using solar cells.

FIG. 17 illustrates an example of a photovoltaic system using solar cells.

### DETAILED DESCRIPTION

The disclosure will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art.

In the specification, the dimensions of layers and regions are exaggerated for clarity of illustration. It will also be understood that when a layer (or film) is referred to as being “on” another layer or substrate, it can be directly on the other layer or substrate, or intervening layers may also be present. Also, though terms like a first, a second, and a third are used to describe various regions and layers in various embodiments, the regions and the layers are not limited to these terms. These terms are used to tell one region or layer from another region or layer. Therefore, a layer referred to as a first layer in one embodiment can be referred to as a second layer in another embodiment. An embodiment described and exemplified herein includes a complementary embodiment thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

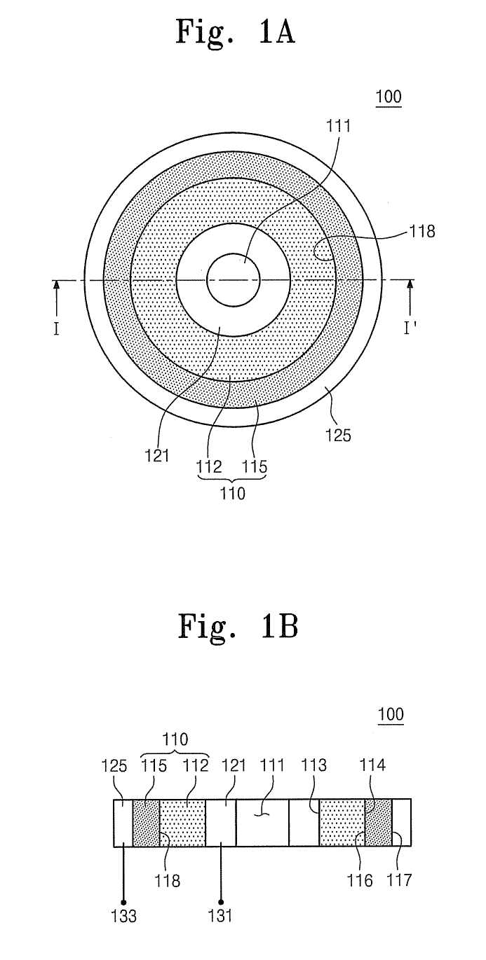

Referring to FIGS. 1A to 1B, a solar cell 100 will now be described. The solar cell 100 may include a light-receiving body 110, which may be provided on a substrate (not shown). The substrate may include a material selected from the group consisting of single-crystalline silicon, silicon on insulator (“SOI”), polysilicon, amorphous silicon, glass, ceramic such as alumina, stainless steel, polymer, metal, silicon germanium (“SiGe”), and single-crystalline germanium.

The light-receiving body 110 may include a first semiconductor region 112 of a first conductivity type and a second semiconductor region 115 of a second conductivity type; the second conductivity type being different from the first conductivity type. For example, the first conductivity type may P-type and the second conductivity type may be N-type. The first semiconductor region 112 and the second semiconductor region 115 may include, for example, silicon (“Si”), gallium arsenide (“GaAs”), gallium indium phosphide (“GaInP”), cadmium telluride (“CdTe”), cadmium sulfide (“CdS”) or Cu(In,Ga)(S,Se)₂ (referred sometimes to as “ClGs”).

The first semiconductor region 112 and the second semiconductor region 115 may be in communication with one another. As can be seen in the FIG. 1A, the first semiconductor region 112 is disposed upon the second semiconductor region 115. In one embodiment, a PN junction 118 may be formed by directly contacting the first and second semiconductor regions 112 and 115 with each other. The contours of the PN junction 118 may be substantially perpendicular to the substrate. That is, the solar cell 100 may have a PN junction 118 in a direction that is perpendicular to the substrate. In one embodiment, the PN junction 118 is circular in shape and has a surface that is perpendicular to a radius drawn from the central axis of the solar cell 100.

With reference now to the FIG. 1B, the first semiconductor region 112 may have a first inner surface 113 and a first outer surface 114. The first outer surface 114 is opposed to the first inner surface 113. The first inner surface 113 may surround a hollow column. That is, the first semiconductor region 112 may have a hollow region 111 at its central portion, and the hollow region 111 may be surrounded by the first inner surface 113. The column may have, for example, a circular section, as shown in FIG. 1. However, the section of the column is not limited to the circular section and may be one of polygonal sections. Other cross-sectional geometries for the column may be square, rectangular, triangular, hexagonal, pentagonal, decagon, tetragon, or the like. The hollow column may be disposed at the center of the inner surface 113 and may be concentric with it. In one embodiment, the hollow column may be disposed within the inner surface 113, but may not be concentric with the surface 113.

The second semiconductor region 115 may have a second inner surface 116 that is in contact with the first outer surface 114 and a second outer surface 117 that is opposed to the first inner surface 116. The PN junction 118 may be formed between the first outer surface 114 and the second inner surface 116.

A first electrode 121 may be in electrical communication with the first semiconductor region 112, for example, in electrical communication with the first inner surface 113. In one embodiment, the first electrode 121 is disposed upon and physically contacts the first inner surface 113 of the first semiconductor region 112. A second electrode 125 may be in electrical communication with the second semiconductor region 115, for example, the second outer surface 117. In one embodiment, the second electrode 125 is disposed upon and physically contacts the second outer surface 117 of the second semiconductor region 116.

The second electrode 125 may be formed of a transparent electrically conductive material. The transparent electrically conductive materials can be inorganic materials, organic materials or combinations thereof. Examples of electrically conductive inorganic materials that can be used for the second electrode 125 are indium tin oxide (“ITO”), indium zinc oxide (“IZO”), zinc oxide (“ZnO”), an alloy of zinc oxide a aluminum (“ZnO:Al”), or the like, or a combination comprising at least one of the foregoing electrically conductive inorganic materials. Examples of electrically conductive organic materials that can be used for the second electrode 125 are polyaniline, polypyrrole, polythiophene, polyacetylene, or the like, or a combination comprising at least one of the foregoing electrically conductive organic materials.

A first lead 131 is in electrical communication with the first electrode 121 and a second lead 133 is in electrical communication with the second electrode 125, transferring the electrical power generated by the solar cell 100 to the exterior.

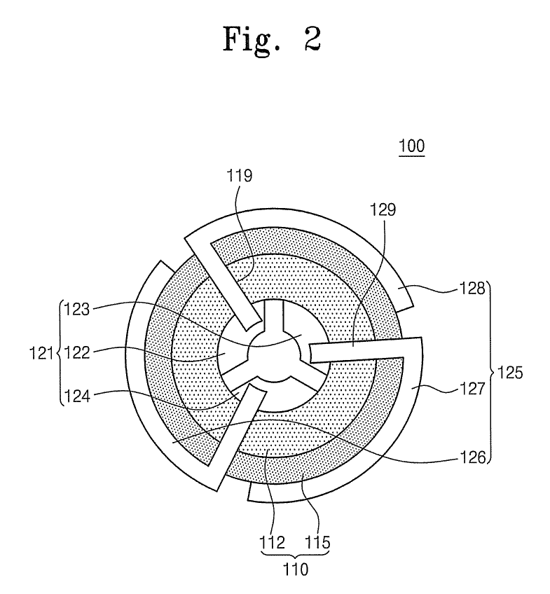

Referring to FIG. 2, the first electrode 121 may include a plurality of sub-electrodes 122, 123, and 124 that are isolated from each other. The second electrode 125 may also include a plurality of second sub-electrodes 126, 127, and 128 that are isolated from each other. The first sub-electrodes 122, 123, and 124 and the second sub-electrodes 126, 127, and 128 may be set to face each other, respectively. The light-receiving body 110 may include at least one isolation recess 119 that intersects with the first inner surface 113 of the first semiconductor region 112. A connection electrode 129 may be provided in the at least one isolation recess 119. The connection electrode 129 may connect one of the first sub-electrodes 122, 123, and 124 to one of the adjacent second sub-electrodes 126, 127, and 128, electrically connecting the first sub-electrodes 122, 123, and 124 to the second sub-electrodes 126, 127, and 128. An insulating spacer (not shown) may be provided on a sidewall of the isolation recess 119 to prevent the connection electrode 129 from coming in direct contact with the light-receiving body 110.

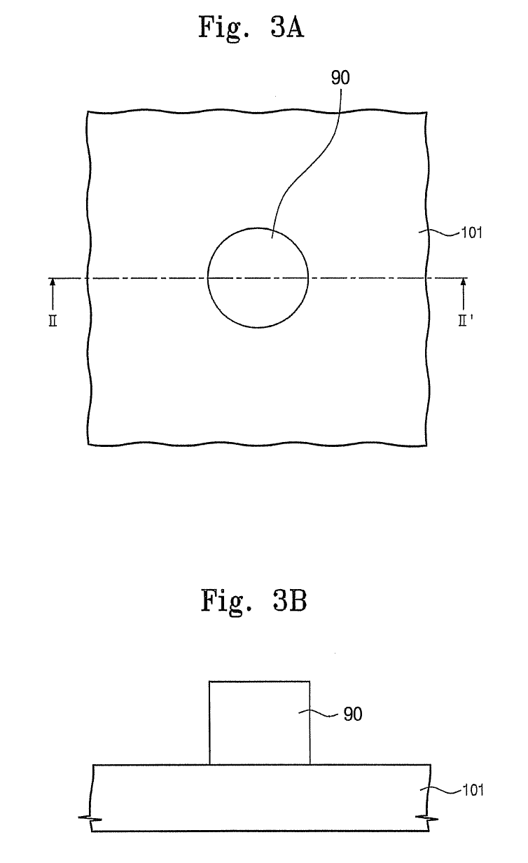

Referring to FIGS. 3A to 7A and FIGS. 3B to 7B, an exemplary method of fabricating a solar cell 100 will now be described.

Referring to FIGS. 3A and 3B, a molding pattern 90 is provided on a substrate 101. The substrate 101 may include a material selected from the group consisting of single-crystalline silicon, silicon on insulator, polysilicon, amorphous silicon, glass, ceramic such as alumina, stainless steel, polymer, metal, silicon germanium, and single-crystalline germanium. The molding pattern 90 may be formed of a material having an etch selectivity with respect to a material constituting the light-receiving body 110 (not shown). The molding pattern 90 may include, for example, silicon oxide. The molding pattern 90 may have a cross-sectional area that exhibits the shape of, for example, a circle, a square, a rectangle, a triangle, or a polygon including hexagons, pentagons, decagons, tetragons, or the like.

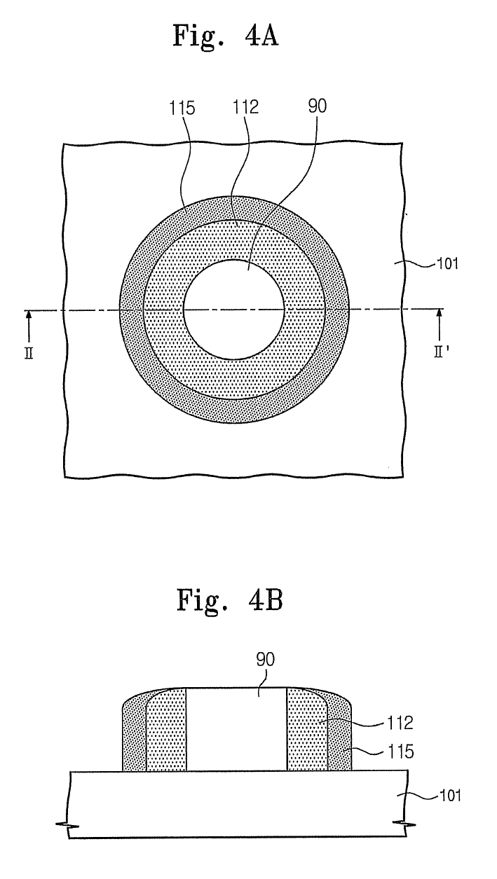

Referring to FIGS. 4A and 4B, a first semiconductor material 112 of a first conductivity type may be formed on a sidewall of the molding pattern 90. The first conductivity type may be P-type. The first semiconductor material 112 may include, for example, GaAs, GaInP, CdTe, CdS or Cu(In,Ga)(S,Se)₂. A second semiconductor material 115 of a second conductivity type may be formed on a sidewall of the first semiconductor material 112. The second conductivity type is different from the first conductivity type. That is, the second conductivity type may be N-type. The second semiconductor material 115 may include, for example, Si, GaAs, GaInP, CdTe, Gds or Cu(In,Ga)(S,Se)₂. The first and second materials 112 and 115 may be formed by, for example, a deposition process using chemical vapor deposition (“CVD”), plasma enhanced chemical vapor deposition (“PECVD”), remote plasma-enhanced chemical vapor deposition (“RPECVD”) hybrid physical-chemical vapor deposition (“HPCVD”), microwave plasma-assisted chemical vapor deposition (“MPCVD”), aerosol assisted chemical vapor deposition (“AACVD”), or the like, or a combination comprising at least one of the foregoing process. The first and second semiconductor materials 112 and 115 may further be formed by an etch-back process.

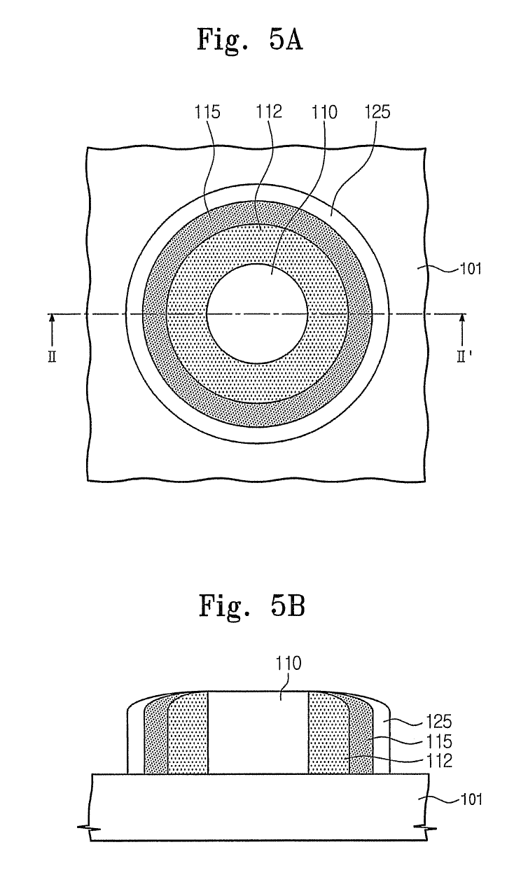

Referring to FIGS. 5A and 5B, a second electrically conductive material 125 (which forms the second electrode 125) may be formed on a sidewall of the second semiconductor material 115. The second electrically conductive material 125 may be a transparent conductive material. As noted above, indium tin oxide, indium zinc oxide, zinc oxide, an alloy of zinc oxide a aluminum, polyaniline, polypyrrole, polythiophene, polyacetylene, or the like, or a combination comprising at least one of the foregoing electrically conductive organic materials may be used as the transparent electrically conductive material. The second conductive material 125 may be formed by, for example, a sputtering deposition process and an etch-back process. When the transparent conductive material comprises an electrically conducting polymer, the material can be applied to the second semiconductor material 115 by coating processes such as spin coating, painting, dip coating, or the like, or a combination comprising at least one of the foregoing processes.

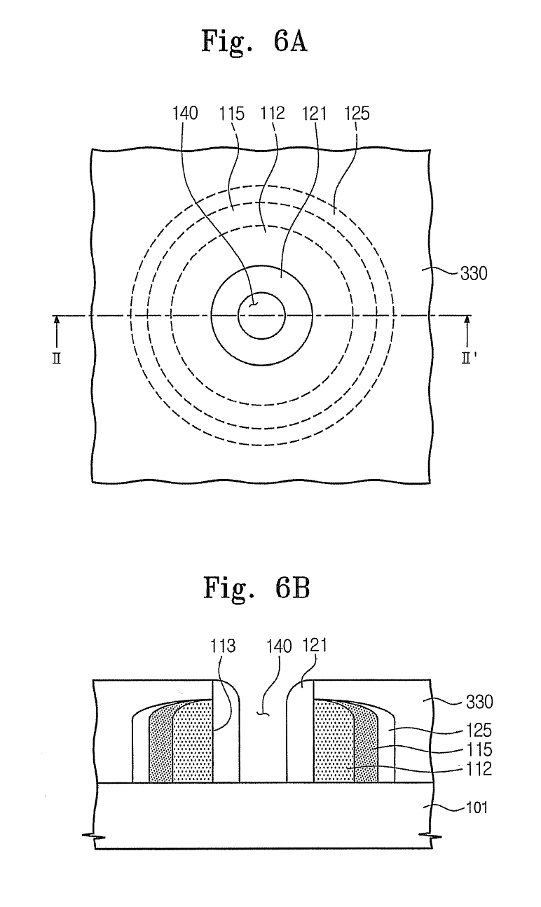

Referring to FIGS. 6A and 6B, the molding pattern 90 may be selectively removed to expose a first inner surface 113 of the first semiconductor material 112. The first inner surface 113 may provide a hollow column, i.e., a hole 114. A mask pattern 330 may be provided to cover the first semiconductor material 112, the second semiconductor material 115, and the second conductive material 125 while exposing the hole 114. The mask pattern 330 may be formed of, for example, silicon oxide. A first conductive material 121 may be formed on the first inner surface 113 of the first semiconductor material 112 and a sidewall of the mask pattern 33. The first conductive material 121 may include a metal such as molybdenum, copper, iron, steel, or the like, or a combination comprising at least one of the foregoing metals. The first conductive material 121 may be formed by, for example, a sputtering deposition process and an etch-back process.

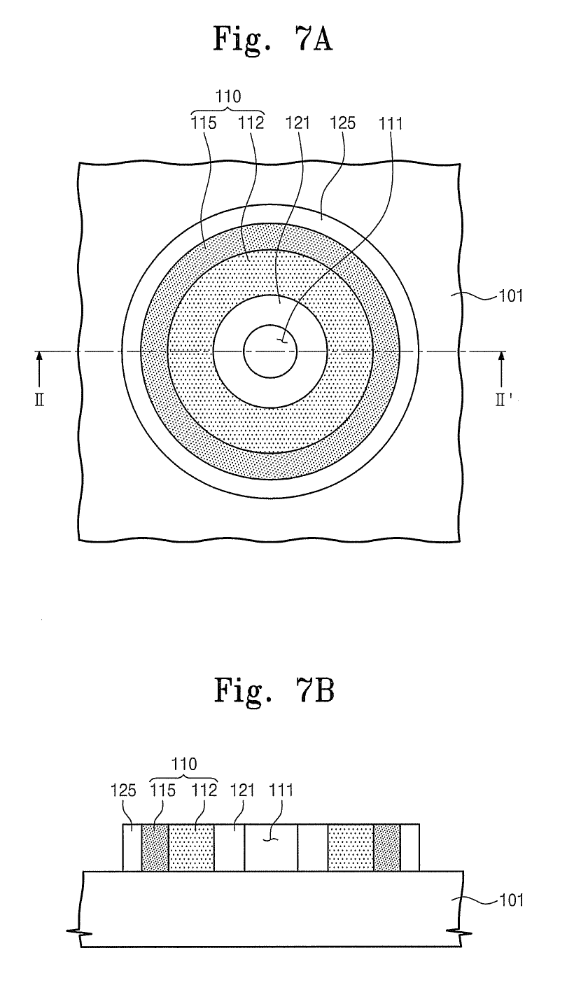

Referring to FIGS. 7A and 7B, a mold layer (not shown) is formed to fill the hole 140. The mold layer, the mask pattern 330, the first conductive material 121, the second semiconductor material 112, the first semiconductor material 115, and the second conductive material 125 may be polished by a chemical mechanical polishing (“CMP”) process. The mold layer and the mask pattern 330 may be removed. A light receiving body 110 may be formed, which includes a first semiconductor region 112 of a first conductivity type and a second semiconductor region 115 of a second conductivity type. A first electrode 121 and a second electrode 125 may be formed on an inner surface and an outer surface of the light-receiving body 110, respectively.

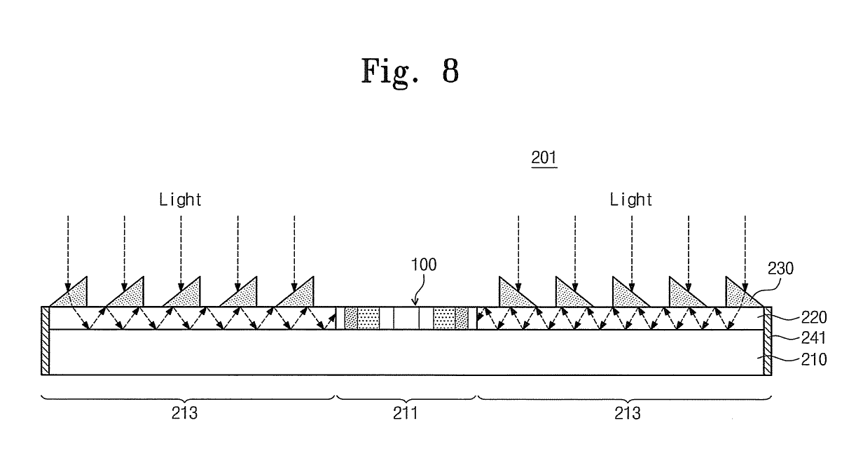

Referring to FIG. 8, a solar cell module 201 will now be described. The solar cell module 201 may include the solar cell 100 described in FIGS. 1A and 1B. The solar cell module 201 may include a support 210, the solar cell 100 being provided on the support 210 to be disposed adjacent to a center area 211 of the support 210, and an optical waveguide 220 provided on the support 210 to be disposed adjacent to an edge portion 213 of the support 210. The solar cell 100 may be provided to expose the edge area 213. The solar cell 100 may have a PN junction surface, which is substantially perpendicular to the support 210.

The support 210 may be made of a material that does not absorb light within a suitable wavelength range that makes only a slight contribution to power generation in the solar cell 100 while simultaneously generating a heat. Generally, light within the infrared range of the electromagnetic spectrum makes only a slight contribution to power generation in the solar cell 100 and generate a heat to degrade the performance of the solar cell 100. For this reason, the support 210 may be made of an infrared-transmitting material.

The optical waveguide 220 may concentrate and direct the incident light to the solar cell 100. The optical waveguide 220 may be set to have a refractive index and a thickness to reduce impingement of light above a specific wavelength on the solar cell 100. The optical waveguide 220 may include a high-k dielectric having a higher refractive index than the support 210. The optical waveguide 220 may comprise a material selected from the group consisting of aluminum oxide, zinc oxide, silicon oxynitride or titanium oxide.

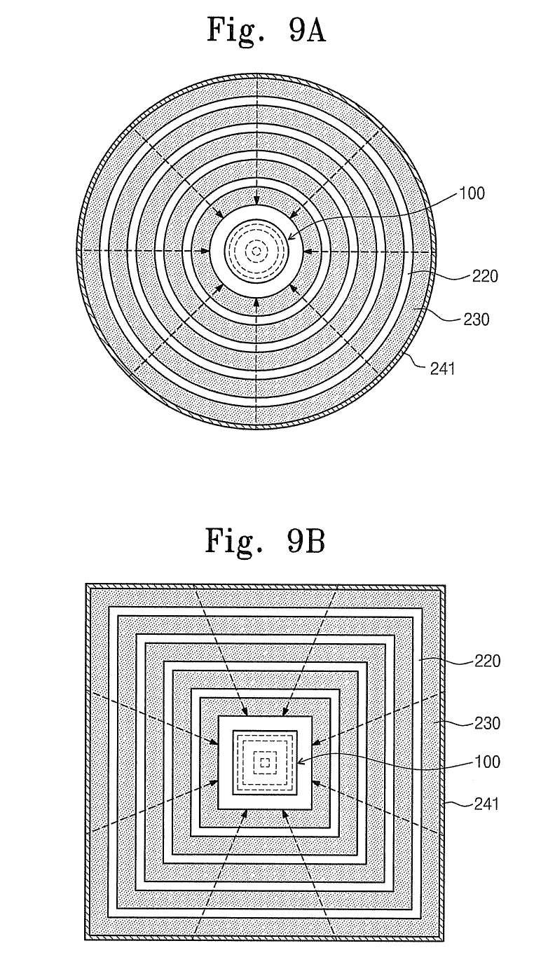

A first optical coupler 230 may be provided on the optical waveguide 220 within the edge area 213. The first optical coupler 230 may be set such that light impinging from the upper portion of the support 210 travels to the solar cell 100 through the optical waveguide 220. The first optical coupler 230 may include a material having the same or a smaller refractive index as compared with the refractive index of the optical waveguide 220. The first optical coupler 230 may extend to surround the solar cell 100 at the edge area 213, forming a closed curve such as circle or polygon, as shown in FIGS. 9A and 9B respectively.

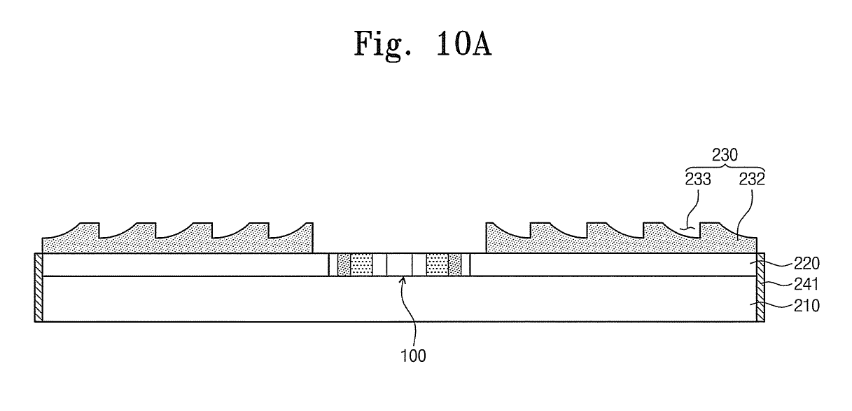

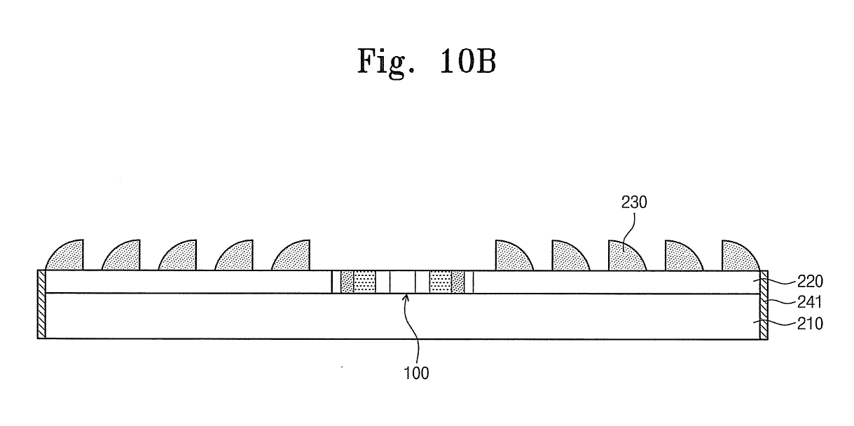

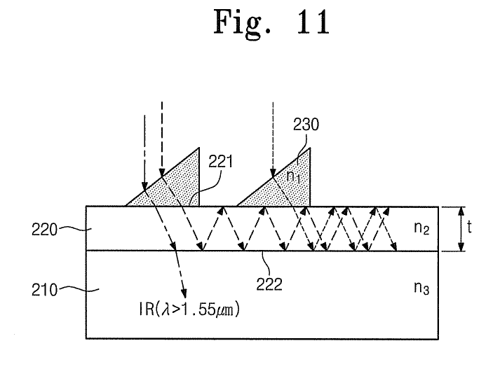

As shown in FIG. 8, an upper surface of the first optical coupler 230 may be inclined toward the edge of the support 210. Alternatively, as shown in FIG. 10A, the first optical coupler 230 may include a coupling thin film 232 covering the edge area 213. The coupling thin film 232 may have a concave portion 233 extending to surround the solar cell 100. The bottom of the concave portion 233 may be inclined toward the edge of the support 210. The surface of the concave portion 233 is concave with respect to the external incident light. Alternatively, as shown in FIG. 10B, a top surface of the coupling thin film 232 may be inclined toward the edge of the support 210 and may be a convex prism. The surface of the convex portion 230 is convex with respect to the external incident light.

A first reflection layer 241 is disposed on an edge sidewall of the optical waveguide 220 such that light directed away from the solar cell may be reflected to travel towards the solar cell 100. The first reflection layer 241 may be a multi-layer structure including silicon oxide and silicon nitride or a layer of metal such as silver. Light within a specific wavelength range may be effectively reflected by suitably adjusting the kind and the thickness of the multi-layer structure.

A procedure for propagating light impinging from the above of the support 210 to the solar cell 100 will now be described below with reference to FIG. 11, in which n₁, n₂, and n₃ represent refractive indexes of the first optical coupler 230, the optical waveguide 220, and the support 210, respectively. The refractive index n₁ of the first optical waveguide 230 may be equal to or smaller than the refractive index n₂ of the optical waveguide 220.

The light impinging on the first optical coupler 230 from above the support 210 may be refracted at the inclined surface of the first optical coupler 230 to travel to the optical waveguide 220. When the reactive index n₁ of the first optical coupler 230 is different from the refractive index n₂ of the optical waveguide 220, the light travelling to the optical waveguide 220 may be refracted again at a first boundary 221 between the first optical coupler 230 and the optical waveguide 220 to enter the optical waveguide 220. The light of the optical waveguide 220 may be refracted or reflected at a second boundary 222 between the optical waveguide 220 and the support 210. Since the refractive index n₂ of the optical waveguide 220 is greater than the refractive index n₃ of the support 210, most of the light from the optical waveguide 220 may be totally reflected at the second boundary 222. The condition of total reflection at the first and second boundaries 221 and 222 is expressed with an equation [Equation 1], in which λ represents the refractive index of light, m represents an integer (m=0, 1, 2, 3), and t represents the thickness of the optical waveguide 220. Although FIG. 11 shows that rays of light travelling to the first optical coupler 230 are all reflected at the first boundary 221, they may be refracted to the first optical coupler 230 to enter the optical waveguide 220 again. Since the refractive index of the first optical coupler 230 is greater than that of air, light entering the first optical coupler 230 may travel to the optical waveguide 220.

$${n}_{2} - {n}_{3} > \frac{{m}^{2} {λ}^{2 }}{4 ( {n}_{2} + {n}_{3} ) {( 2 t )}^{2}} \qquad [ Equation 1 ]$$

When the material of the support 210 is determined, light within a wavelength range that can be absorbed by the solar cell 100 is substantially and totally reflected at the second boundary 222 to be propagated within the optical waveguide 220 by adjusting the thickness and the refractive index of the optical waveguide 220 according to the equation [Equation 1]. According to the equation [Equation 1], light of a greater wavelength than the total reflection wavelength (e.g., infrared light) may be substantially transmitted to the support 210 without being totally reflected at the second boundary 222. Thus, light of a greater wavelength than the total reflection wavelength may be lost at the optical waveguide 220 during its propagation. That is, light of a greater wavelength than the total reflection wavelength may not be substantially transmitted to the solar cell 100. For instance, in case of a group III-V multijunction solar cell using InGaAsP or the like, light of a wavelength below 1.55 micrometers may be transmitted to the solar cell 100.

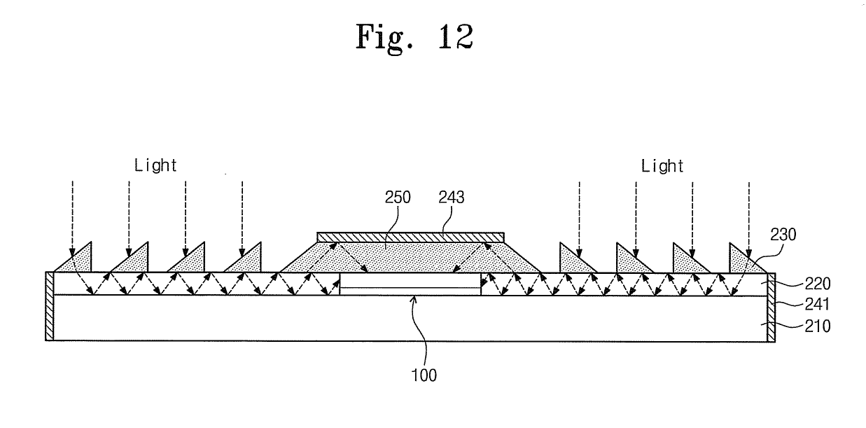

Referring to FIG. 12, a solar cell module 202 according to other embodiments will now be described. Explanations of the same or similar elements in FIG. 12 as those in FIG. 8 will be omitted, but their differences will be explained in detail. The solar cell module 203 may include a second optical coupler 250 and a second reflection layer 243, which reflects light impinging on a top surface of the second optical coupler 250 to the solar cell 100. The second reflection layer 243 may be a multi-layer structure including silicon oxide and silicon nitride or a layer of metal such as silver. Light within a specific wavelength range may be effectively reflected by suitably adjusting the kind and thickness of the multi-layer structure. The solar cell 100 may have a PN junction surface, which is substantially parallel with the support 210. The second optical coupler 250 may be made of the same material as the first optical coupler 230.

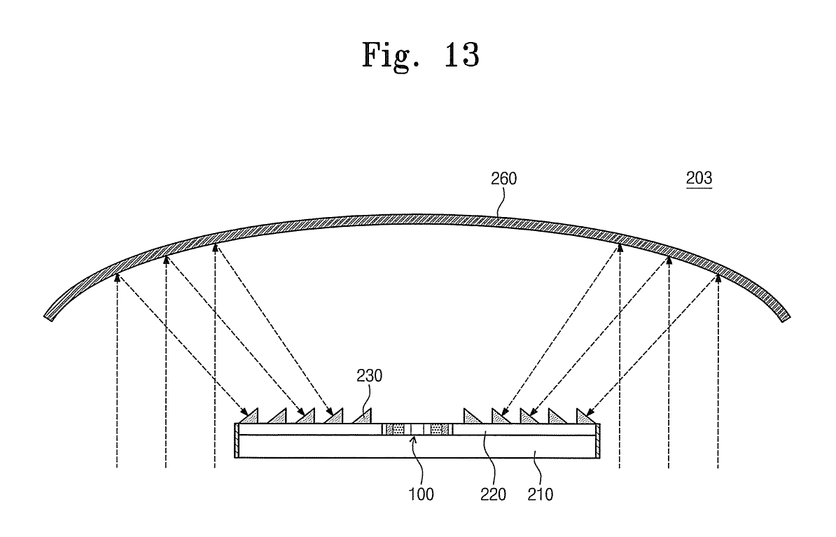

Referring to FIG. 13, a solar cell module 203 will now be described. Explanations of the same or similar elements in FIG. 13 as those in FIG. 8 will be omitted, but their differences will be explained in detail. The solar cell module 203 may include an external reflection mirror 260 spaced apart from the optical waveguide 220 over the support 210. The external reflection mirror 260 may cover up the support 210 and be concave toward the support 210. Light impinging from below the support 210 may be reflected by the external reflection mirror 260 to impinge on the first optical coupler 230 and the optical waveguide 220. As a result of this arrangement, light of a larger cross section may be concentrated and redirected to the solar cell 100.

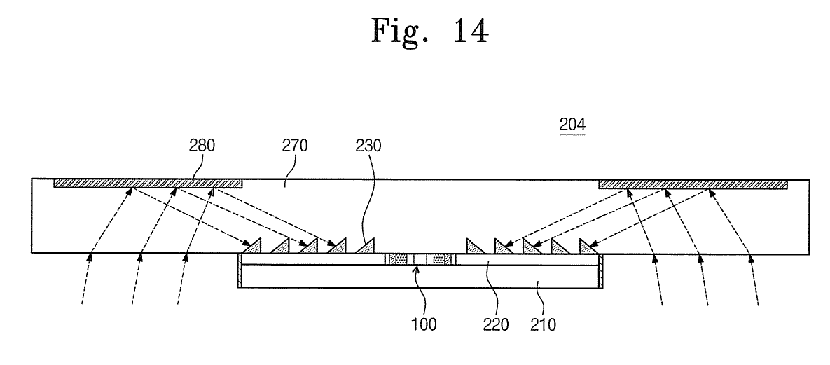

Referring to FIG. 14, a solar cell module 204 according to other embodiments will now be described. Explanations of the same or similar elements in FIG. 14 as those in FIG. 8 will be omitted, but their differences will be explained in detail. The solar cell module 204 may include a light-transmitting panel 270 covering the optical waveguide 220 and having a larger area than the support 210. The solar cell module 204 includes a reflection structure 280 provided on a top surface of the light-transmitting panel 270 to reflect light to the light waveguide 220.

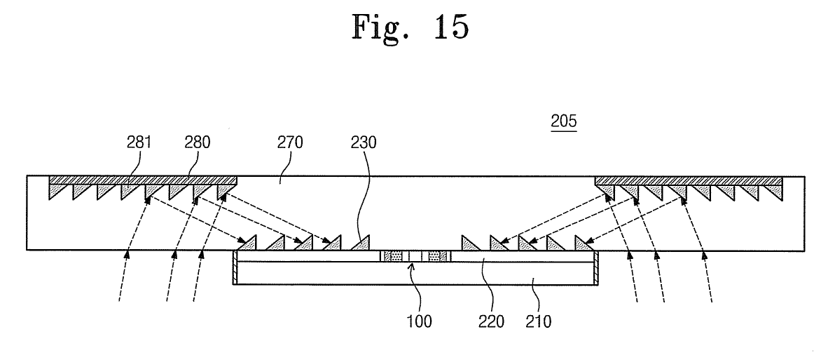

The light-transmitting panel 270 may be made of a light-transmitting material such as, for example, glass. The reflection structure 280 may be a light-reflecting layer, which, may for example be a multi-layer structure including silicon oxide and silicon nitride or a layer of metal such as silver. Light within a specific wavelength range may be effectively reflected by suitably adjusting the kind and thickness of the multi-layer structure. As illustrated in FIG. 15, the reflection structure 280 may include a prism 281 protruding to the light-transmitting panel 270. The prism 281 may have a greater refractive index than the light-transmitting panel 270. A bottom surface of the prism 281 may have a surface inclined toward the center of the light-transmitting panel 270. Light reflected by the inclined surface may impinge on the first optical coupler 230.

According to the above-described embodiments, impingement of light within the wavelength range effective to make a small contribution to power generation on a solar cell may be reduced as much as possible. This is done to prevent efficiency degradation, which occurs when long-wavelength light such as ultraviolet light makes a contribution that increases the inner temperature of the solar cell. It is also desirable to assemble the light condensing unit (i.e., the reflection layer and a reflection structure) with the solar cell in such a manner so that misalignment may not occur thereby preventing any degradation in efficiency of the solar cell.

In the aforementioned embodiments, it is set forth that one solar cell is provided at the center area of the support to form the solar cell module. However, a plurality of solar cells may also be provided on a single support.

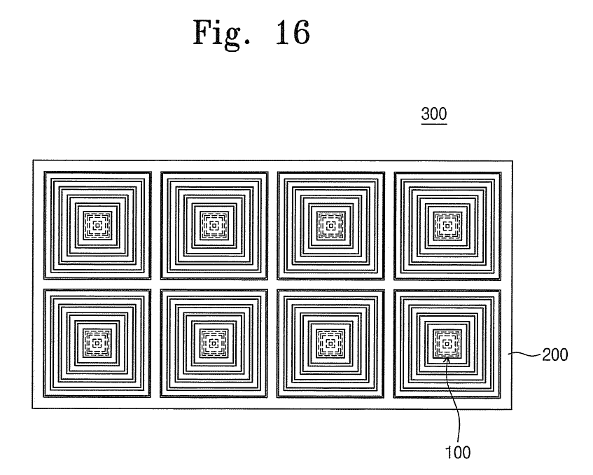

Referring to FIG. 16, a solar cell array 300 using a solar cell module will now be described. The solar cell array 300 may include at least one solar cell module 200 mounted at a main frame (not shown). The solar cell module 200 may include those solar cell modules previously described in FIGS. 8 to 15. The solar cell array 300 may be mounted so as to be fully exposed to the sun at all times. In one embodiment, the solar cell array 300 may be mounted at a regular angle toward the south to be fully exposed to the sun.

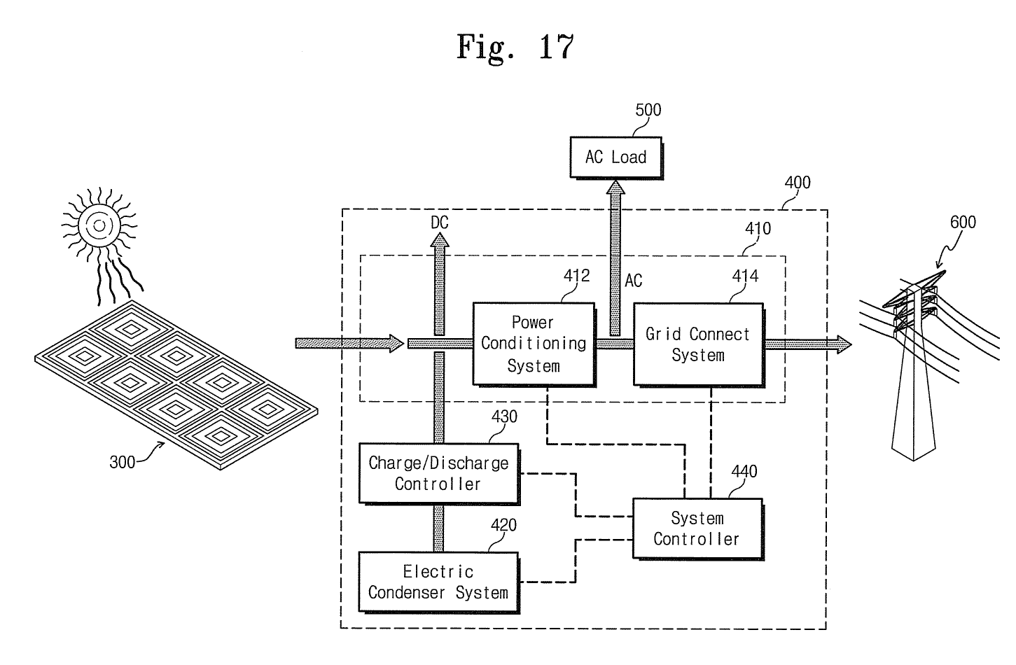

The above-described solar cell module or solar cell array may be mounted on automobiles, houses, buildings, ships, lighthouses, traffic signal systems, portable electronic devices, and various structures. Referring to FIG. 17, an example of a photovoltaic power generation system employing solar cells according to embodiments will now be described. The photovoltaic power generation system may include a solar cell array 300 and a power control system 400 transmitting power provided from the solar cell array 300 to the exterior. The power control system 400 may include an output unit 410, an electric condenser system 420, a charge/discharge controller 430, and a system controller 440. The output unit 410 may include a power conditioning system (“PCS”) 412.

The PCS 412 may be an inverter for converting direct current from the solar cell array 300 to alternating current. Since sunlight does not exist at night is significantly reduced on cloudy days, power generation may be reduced too. The electric condenser system 420 may store electricity to prevent power generation from changing with the weather. The charge/discharge controller 430 may store power provided from the solar cell array 300 in the electric condenser system 420 or output to the electricity stored in the electric condenser system 420 to the output unit 410. The system controller 440 may control the output unit 410, the electric condenser system 420, and the charge/discharge controller 430.

As mentioned above, converted alternating current may be supplied to various AC loads 500 such as home and automobiles. The output unit 410 may further include a grid connect system 414, which may provide connections to another power system 600 to transmit power to the exterior.

According to the embodiments, the manufacturing cost of solar cells can be reduced and efficiency of the solar cells can be improved. Moreover, disadvantages resulting from optical misalignment can be addressed.

Although the present invention has been described in connection with the embodiments illustrated in the accompanying drawings, it is not limited thereto. It will be apparent to those skilled in the art that various substitutions, modifications and changes may be made without departing from the scope and spirit of the invention.

What is claimed is:

1. A solar cell comprising:
a substrate;
a light-receiving body provided on the substrate; the light-receiving body comprising:
a first semiconductor region of a first conductivity type; and
a second semiconductor region of a second conductivity type; the second conductivity type being different from the first conductivity type; the first and second semiconductor regions being in communication with each other and having a PN junction surface that is substantially perpendicular to the substrate.

2. The solar cell as set forth in claim 1, wherein the first semiconductor region has a hollow column and comprises a first inner surface and a first outer surface; the first outer surface facing the first inner surface, the second semiconductor region comprises a second inner surface being in contact with the first outer surface, and wherein the PN junction surface is disposed between the first outer surface and the second inner surface.

3. The solar cell as set forth in claim 2, further comprising a first electrode being in contact with the first inner surface of the first semiconductor region; and a second electrode being in contact with a second outer surface of the second semiconductor region, the second outer surface being opposed to the second inner surface.

4. The solar cell as set forth in claim 3, wherein the second electrode comprises a transparent electrically conductive material.

5. The solar cell as set forth in claim 3, wherein the first electrode comprises a plurality of first sub-electrodes isolated from each other, and the second electrode comprises a plurality of second sub-electrodes isolated from each other, and the light-receiving body includes at least one isolation recess crossing the second outer surface of the second semiconductor region from the first inner surface of the first semiconductor region.

6. The solar cell as set forth in claim 5, further comprising a connection electrode provided in the at least one isolation recess, wherein the first sub-electrodes and the second sub-electrode are set to face each other, and the connection electrode connects one of the first sub-electrodes to adjacent one of the second sub-electrodes to electrically connect the first sub-electrodes with the second sub-electrodes in series.

7. A solar cell module comprising:
a support;
a solar cell disposed adjacent to a center area of the support; the solar cell being disposed on the support in a manner effective to expose an edge area of the support; and
an optical waveguide layer provided on the edge area of the support; the optical waveguide being operative to concentrate light on the solar cell.

8. The solar cell module as set forth in claim 7, wherein the solar cell has a PN junction surface that is substantially perpendicular to the support.

9. The solar cell module as set forth in claim 7, wherein the optical waveguide layer has a refractive index and a thickness to reduce impingement of light above a wavelength of 1.55 micrometers on the solar cell.

10. The solar cell module as set forth in claim 9, wherein light having a wavelength that can be effectively absorbed by the solar cell is substantially and totally reflected at the boundary between the support and the optical waveguide layer, while light of a wavelength longer than the wavelength that can be effectively absorbed by the solar cell is substantially transmitted at the boundary between the support and the optical waveguide layer.

11. The solar cell module as set forth in claim 7, further comprising a first optical coupler allowing light impinging from the above of the support to travel to the solar cell through the optical waveguide.

12. The solar cell module as set forth in claim 11, further comprising a second optical coupler covering the solar cell; and a reflection layer allowing light impinging on a top surface of the second optical coupler to be reflected to the second optical coupler, wherein the solar cell has a PN junction surface that is substantially perpendicular to the support.

13. The solar cell module as set forth in claim 7, further comprising a reflection layer provided on a sidewall formed at the edge of the optical waveguide layer and reflecting the light to travel to the solar cell.

14. The solar cell module as set forth in claim 7, further comprising an external reflection mirror covering up the support while being spaced apart from the optical waveguide layer over the support, the external reflection mirror being concave toward the support.

15. The solar cell module as set forth in claim 7, further comprising a light-transmitting panel covering the optical waveguide and having a larger area than the support; and a reflection structure provided at a top surface of the light-transmitting panel to reflect light to the optical waveguide layer.
